(19) United States
(12) Patent Application Publication
(10) Pub. No.: US 2003/0232563 A1
(43) Pub. Date: Dec. 18, 2003

(54) Method and apparatus for manufacturing organic electroluminescence device, and system and method for manufacturing display unit using organic electroluminescence devices

(76) Inventors: Isao Kamiyama, Kanagawa (JP); Takao Mori, Kanagawa (JP); Masaru Yamaguchi, Kanagawa (JP)

Correspondence Address: ROBERT J. DEPKE LEWIS T. STEADMAN, HOLLAND & KNIGHT LLC, 131 SOUTH DEARBORN, 30TH FLOOR, CHICAGO, IL, 60603, US

(21) Appl. No.: 10/428,411

(22) Filed: May 2, 2003

(30) Foreign Application Priority Data
May 9, 2002 (JP) JP2002-133536

(51) Int. Cl. H01J 9/00

(52) U.S. Cl. 445/24

(57) ABSTRACT

In manufacturing an organic electroluminescence device including a plurality of layers sequentially laminated on a substrate, the plurality of layers are laminated at a film formation portion on the substrate by varying the relative positions of the substrate on which to perform film formation and a plurality of vapor sources arranged side by side so that the substrate passes sequentially through positions corresponding to the plurality of vapor sources.

### BACKGROUND OF THE INVENTION

The present invention relates to a method and an apparatus for manufacturing an organic electroluminescence device (hereinafter referred to as “organic EL device”), and a system and a method for manufacturing a display unit using the organic EL devices.

In recent years, as a planar-type display unit, one that uses organic EL devices as light-emitting devices (hereinafter referred to as “organic EL display”) has been paid attention to. The organic EL display is a self-light-emitting type flat panel display which does not require a backlight, and has the merit of being capable of realizing a display with a wide angle of visibility which is peculiar to the self-light-emitting type. In addition, the organic EL display is advantageous over the backlight type (liquid crystal display and the like) in that it is only necessary to turn ON only the required pixels, and is considered to have a sufficient response performance for a high-definition high-speed video signal which is expected to be put into practical use in the future.

The organic EL device for use in such an organic EL display generally has a structure in which an organic material is sandwiched between electrodes (an anode and a cathode) from the upper and lower sides. Holes are injected from the anode into an organic layer formed of the organic material, while electrons are injected from the cathode into the organic layer, and the holes and the electrons are re-coupled in the organic layer, resulting in emission of light. In this instance, in the organic EL device, a luminance of several hundreds to several tens of thousands of cd/m² is obtained under a driving voltage of not more than 10 V. Besides, by appropriately selecting the organic material (fluorescent material), it is possible to obtain light emission in a desired color. Due to these features, the organic EL device is deemed to be very promising as a light-emitting device for constituting a multi-color or full-color display unit.

Meanwhile, the organic layer in the organic EL device is generally comprised of a lamination of three to five layers such as a hole injection layer, a pole transport layer, a light-emitting layer, a charge injection layer, etc. It should be noted here that the organic materials forming the component layers are low in water resistance, so that a wet process cannot be utilized. Therefore, in forming the organic layer, it is a general practice to sequentially form the component layers by vacuum vapor deposition utilizing a vacuum thin film forming technology, thereby obtaining the desired laminate structure. Besides, in the case of performing a full-color image display, for example, organic layers formed of three kinds of organic materials corresponding to R (red), G (green) and B (blue) color components must be formed at different pixel positions, respectively. Therefore, in forming the organic layers coping with the color display, there has been used a technique in which patterning film formation is conducted for sequentially forming the component layers on a color component basis by replacing, one after another, masks provided with opening patterns corresponding respectively to the color components or by position-matching the masks with the same pattern each time of forming each component layer.

However, according to the conventional technique, the formation of the organic layer in the organic EL device is considered to be attended by the following difficulties.

For example, in forming the organic layer having the laminate structure in the prior art, a technique of changing the vapor source (the kind of the organic material) in a vacuum chamber each time of forming each component layer may have been used. In this case, extra time is taken for raising the temperature of the organic materials for three to five times on a color component basis, and time is needed for performing stabilization of the evaporation rate. Therefore, it is difficult to speedily form the organic layer, and, as a result, there may be a difficulty as to the tact time in manufacturing the organic EL device.

In addition, in the prior art, there may have been used a technique in which, for example, a plurality of vapor sources are arranged in the same vacuum chamber and each of the vapor sources is covered with a shutter or the like which can be opened and closed so that selective formation of each component layer can be performed speedily. In this case, however, a period of time of several tens of minutes is needed for stably maintaining the temperature of the organic material for forming each component layer, so that even the organic materials being covered with the shutter or the like and not being used for forming the layer would be much consumed until the evaporation rate is stabilized. Namely, when the selective film formation is performed, the organic materials would be wasted, and the increases in the material consumption may cause a rise in the cost of the organic EL device.

Furthermore, a system may be contemplated in which the component layers are formed respectively in different vacuum chambers, i.e., one vacuum chamber corresponds to one organic material. In this case, however, a multiplicity of vacuum chambers are required as the organic layer is composed of a multiplicity of component layers, so that there are difficulties as to the equipment cost, installation space and the like.

### SUMMARY OF THE INVENTION

Accordingly, it is an object of the present invention to provide a method and an apparatus for manufacturing an organic EL device, and a system and a method for manufacturing a display unit using the organic EL devices, by which the organic EL device can be manufactured speedily and at low cost through enabling it to form films with a short tact time and small material consumptions.

In accordance with one aspect of the present invention, in order to attain the above object, there is provided a method of manufacturing an organic EL device including a plurality of layers sequentially laminated on a substrate, wherein the plurality of layers are laminated at a film formation portion on the substrate by varying the relative positions of the substrate and a plurality of vapor sources arranged side by side so that the substrate passes sequentially through positions opposed to the plurality of vapor sources.

In accordance with another aspect of the present invention, in order to attain the above object, there is provided an apparatus for manufacturing an organic EL device including a plurality of layers sequentially laminated on a substrate, wherein a plurality of vapor sources corresponding to the plurality of layers are arranged in an aligned manner, and a conveying means is provided for varying the relative positions of the substrate and the plurality of vapor sources so that a film formation portion on the substrate passes sequentially through positions opposed to the plurality of vapor sources.

In accordance with a further aspect of the present invention, in order to attain the above object, there is provided a system for manufacturing a display unit using organic EL devices each of which includes a plurality of layers sequentially laminated on a substrate, wherein the manufacturing system includes a plurality of apparatuses for manufacturing an organic EL device, in each of which a plurality of vapor sources corresponding to the plurality of layers are arranged in an aligned manner, and a conveying means is provided for varying the relative positions of the substrate and the plurality of vapor sources so that a film formation portion on the substrate passes sequentially through positions opposed to the plurality of vapor sources, and the manufacturing apparatuses form the organic EL devices corresponding to different color components respectively.

In accordance yet another aspect of the present invention, in order to attain the above object, there is provided a method of manufacturing a display unit using organic EL devices each of which includes a plurality of layers sequentially laminated on a substrate, wherein the relative positions of the substrate and a plurality of vapor sources arranged side by side are varied so that the substrate passes sequentially through positions opposed to the plurality of vapor sources, to thereby laminate the plurality of layers at a film formation portion on the substrate and to form an organic EL device corresponding to one color component, and this process is repeated a plurality of times while changing the film formation portion on the substrate so as thereby to manufacture the display unit in which the organic EL devices corresponding to a plurality of color components are arranged on the substrate.

According to the method for manufacturing an organic EL device including the above-mentioned procedure and the apparatus for manufacturing an organic EL device constituted as above-mentioned, the film formation of a vapor deposition material from each vapor source at the film formation portion on the substrate is conducted each time the substrate passes sequentially through each of the positions opposed to the vapor sources. Namely, when the substrate has sequentially passed through the positions opposed to the vapor sources, the plurality of layers are sequentially formed at the film formation portion on the substrate. Therefore, in forming the plurality of layers on the substrate, the preparatory treatments (raising of temperature, stabilization of vapor deposition rate, etc.) for each of the vapor sources can be conducted substantially simultaneously, and, even in this case, the vapor deposition materials from the vapor sources are wastelessly used for film formation.

In addition, according to the system for manufacturing a display unit constituted as above-mentioned and the method for manufacturing a display unit including the above-mentioned procedure, an organic EL device including a plurality of layers sequentially laminated on each other is formed, in the same manner as in the above-mentioned method for manufacturing an organic EL device and the above-described apparatus for manufacturing an organic EL device, and this process is repeated a number of times corresponding to a plurality of color components. Therefore, even in the case of manufacturing a display unit including a plurality of organic EL devices arranged on a substrate, formation of each of the organic EL devices can be performed continuously, and it is possible to realize enhancement of efficiency of the preparatory treatments for film formation and vapor deposition material consumptions with respect to each of the organic EL devices.

Thus, according to the method and apparatus for manufacturing an organic EL device and the system and method for manufacturing a display unit using organic EL devices according to the present invention, the relative positions of the substrate on which to form the organic EL device and the plurality of vapor sources arranged side by side are varied so that the substrate passes sequentially through positions opposed to the vapor sources, to thereby sequentially laminate the plurality of layers at the film formation portion on the substrate. Therefore, it is possible to form the layers with a shorter tact time and less material consumptions as compared with those in the prior art, and, as a result, it is possible to manufacture the organic EL device speedily and at low cost.

The above and other objects, features and advantages of the present invention will become apparent from the following description and appended claims, taken in conjunction with the accompanying drawings which show by way of example some preferred embodiments of the invention.

### BRIEF DESCRIPTION OF THE DRAWINGS

FIG. 1 is a schematic diagram showing an example of general constitution of a manufacturing apparatus according to the present invention;

FIGS. 2A and 2B are schematic diagrams of an example of constitution of an essential part of the manufacturing apparatus according to the present invention, in which FIG. 2A is a front view of the essential part, and FIG. 2B is a side view of the essential part;

FIG. 3 is a schematic diagram showing an example of general constitution of an organic EL device manufactured by the manufacturing apparatus according to the present invention;

FIG. 4 is a schematic diagram showing an example of general constitution of a conveying jig used in manufacturing an organic EL device; and

FIG. 5 is a schematic diagram showing an example of constitution of a system for manufacturing a display unit using organic EL devices according to the present invention.

### DETAILED DESCRIPTION OF THE PREFERRED EMBODIMENTS

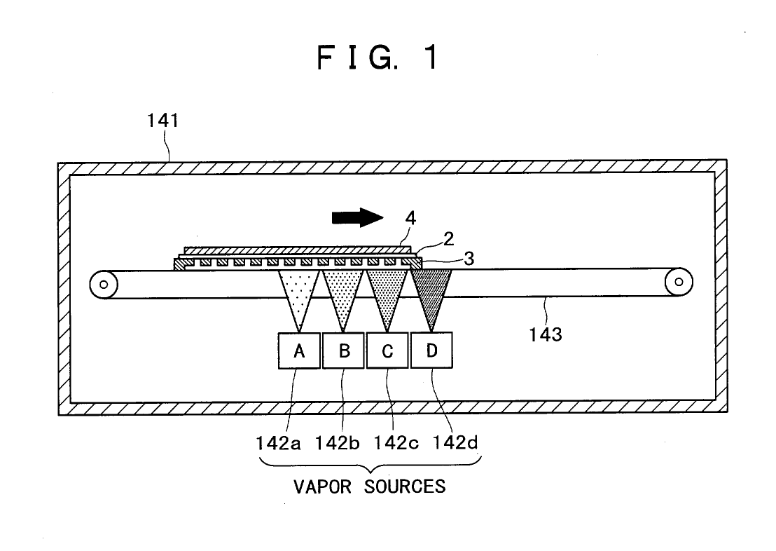

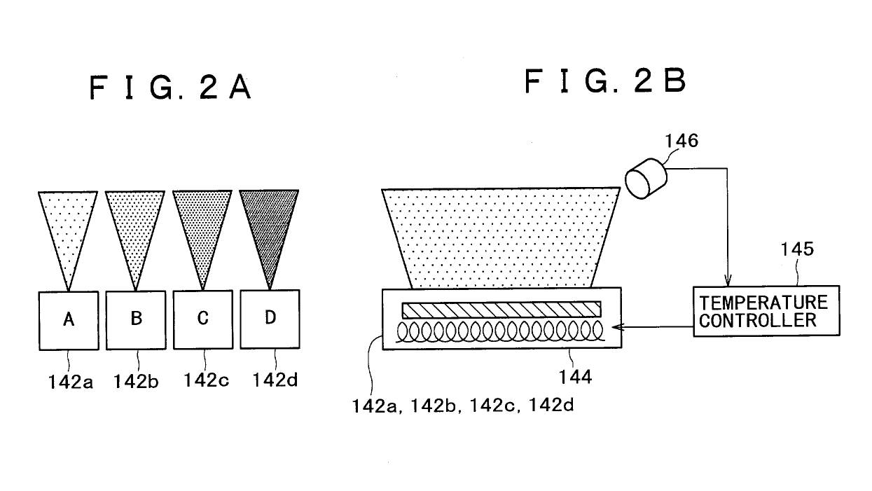

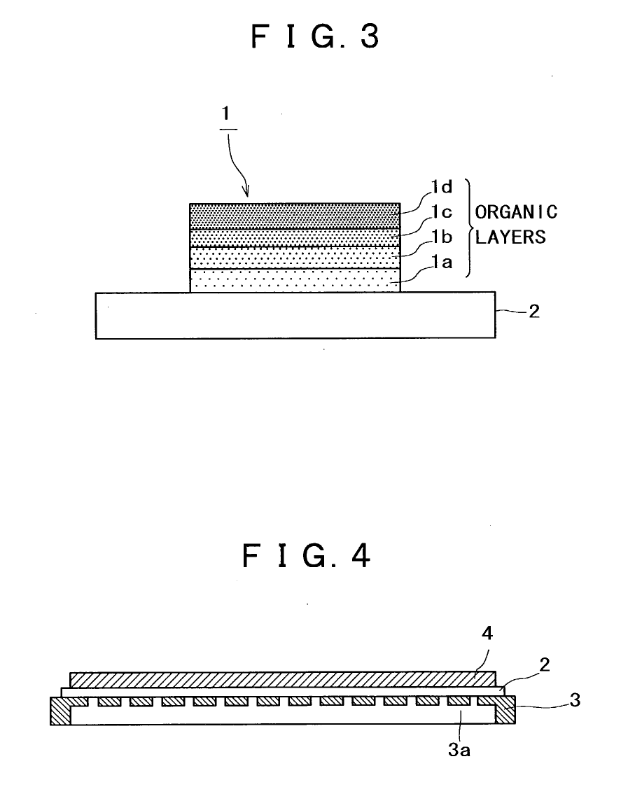

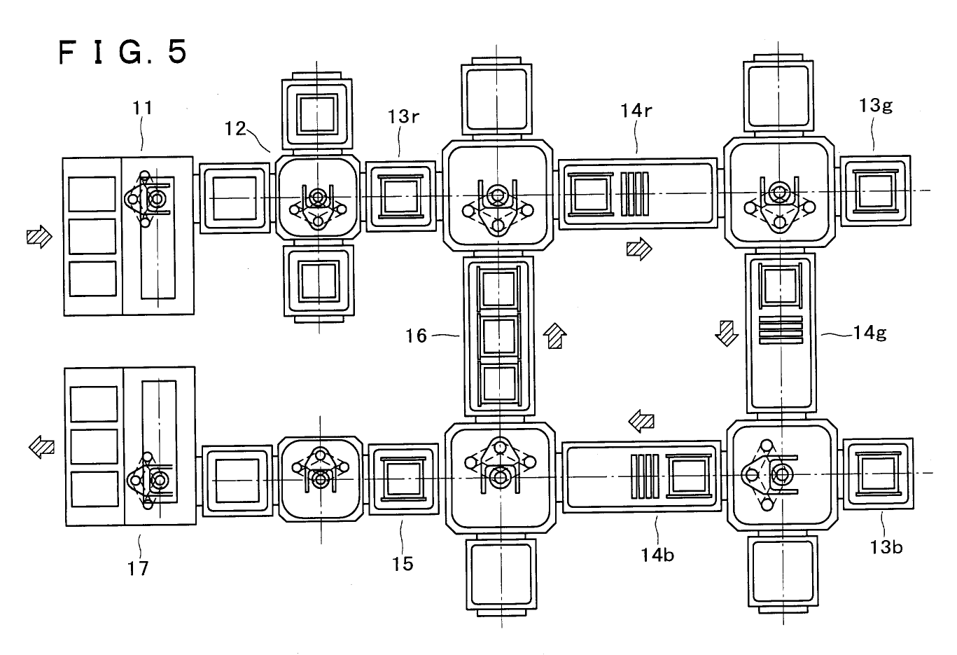

Now, the method and apparatus for manufacturing an organic EL device and the system and method for manufacturing a display unit using organic EL devices according to the present invention will be described below based on the drawings, in which FIG. 1 is a schematic diagram showing an example of general constitution of the manufacturing apparatus according to the present invention; FIGS. 2A and 2B are schematic diagrams showing an example of constitution of an essential part of the manufacturing apparatus; FIG. 3 is a schematic diagram showing an example of general constitution of an organic EL device manufactured by the manufacturing apparatus; FIG. 4 is a schematic diagram showing an example of general constitution of a conveying jig used in manufacturing the organic EL device; and FIG. 5 is a schematic diagram showing an example of constitution of the manufacturing system using the manufacturing apparatus according to the present invention.

First, general constitution of the organic EL device will be described in brief. As shown in FIG. 3, the organic EL device 1 manufactured in the present embodiment is formed on a glass substrate 2 for constituting an organic EL display, and comprises a plurality of organic layers 1a to id which are formed of different materials and are sequentially laminated on the glass substrate 2. While the case where four layers are laminated is shown here, this constitution is naturally not limitative.

Though not shown, a plurality of organic EL devices 1 corresponding for example to R, G and B color components are arranged in a predetermined matrix pattern on the glass substrate 2. The differences between the organic EL devices 1 lie in the organic materials (fluorescent materials) constituting the organic layers 1a to 1d. By this, in the organic EL display comprising the glass substrate 2 and the organic EL devices 1, display of a color image can be achieved by selectively causing the organic EL devices to generate light with predetermined wavelengths.

The arrangement of the organic EL devices 1 for displaying such a color image can be realized by forming the organic EL devices by patterning film formation corresponding to each of R, G and B color components, for example. Here, general constitution of a conveying jig for use in the patterning film formation will be described. As shown in FIG. 4, the patterning film formation is carried out by use of a metal mask 3 which is flat plate-like in shape and is formed of a ferromagnetic material such as iron (Fe) and nickel (Ni). The metal mask 3 is provided with a plurality of openings 3a corresponding to a predetermined film formation pattern. The metal mask 3 is fixed in the condition of close contact with the glass substrate 2 on which to form the film, so as to cover one side of the glass substrate 2, by a magnetic force generated by a magnet 4 disposed on the other side of the glass substrate 2. By use of such an integral-type conveying jig, film formation in a predetermined pattern can be achieved on the glass substrate 2. Besides, when a plurality of kinds of metal masks 3 are prepared, it is possible to form a multi-layer film in different layer patterns, and, as a result, it is possible to arrange a plurality of organic EL devices 1 in a matrix pattern.

Next, a system for manufacturing an organic EL display unit by forming organic EL devices 1 on a glass substrate 2 by use of the above-mentioned conveying jig will be described. The manufacturing system to be described in the present embodiment is for arranging a plurality of organic EL devices 1 in a matrix pattern on the glass substrate 2 through patterning film formation corresponding to each of R, G and B color components so as to constitute the organic EL display capable of displaying a color image.

For this purpose, as shown in FIG. 5, the manufacturing system to be described in the present embodiment is generally comprised of a substrate supply station 11 to which the glass substrate 2 is supplied from the exterior, a pre-treatment station 12 for performing pre-treatments such as cleaning and activation on the glass substrate 2, an R color alignment station 13r for performing alignment (position matching of the glass substrate 2 and a metal mask 3 and fixing thereof) corresponding to R color, an R color film formation station 14r for performing patterning film formation corresponding to the R color, a G color alignment station 13g for performing alignment corresponding to G color, a G color film formation station 14g for performing patterning film formation corresponding to the G color, a B color alignment station 13b for performing alignment corresponding to B color, a B color film formation station 14b for performing patterning film formation corresponding to the B color, an after-treatment station 15 for performing after-treatments such as separation between the glass substrate 2 and the metal mask 3, a return station 16 for feeding the metal mask 3 separated from the glass substrate 2 and the like to the R color alignment station 13r, and a substrate discharge station 17 for discharging the glass substrate 2 provided thereon with the organic EL devices 1 corresponding to the respective colors by the patterning film formation.

Of these stations 11 to 17, the R color film formation station 14r, the G color film formation station 14g and the B color film formation station 14b correspond to the apparatuses for manufacturing the organic EL devices described in the present embodiment. Namely, the R color film formation station 14r, the G color film formation station 14g and the B color film formation station 14b form the organic EL devices 1 corresponding to the R, G and B color components, respectively.

Within the range from the R color alignment station 13r to the after-treatment station 15, the glass substrate 2 is dealt with in the state of constituting an integral-type conveying jig together with the metal mask 3 and the magnet 4. Therefore, the conveying jig constituted of the glass substrate 2, the metal mask 3 and the magnet 4 passes sequentially through the R color film formation station 14r, the G color film formation station 14g and the B color film formation station 14b.

In addition, since the R color alignment station 13r, the G color alignment station 13g and the B color alignment station 13b are arranged on the previous stage of the R color film formation station 14r, the G color film formation station 14g and the B color film formation station 14b, respectively, it is possible to cope with alignment (patterning film formation) in mutually different conditions. The transfer, alignment adjustments and the like of the glass substrate 2 or the conveying jig among these stations 11 to 17 are carried out by use of known handling robots, conveyors and the like, though description thereof is omitted here.

Further, these stations 11 to 17 form a closed loop structure due to the presence of the return station 16. Therefore, the metal mask 3 and the magnet 4 constituting the conveying jig are circulated in the closed loop comprised of the R color film formation station 14r, the G color film formation station 14g, the B color film formation station 14b and the return station 16. Specifically, the R color film formation station 14r, the G color film formation station 14g, the B color film formation station 14b and the return station 16 are laid out in a rectangular pattern with the R color alignment station 13r, the G color alignment station 13g, the B color alignment station 13b and the after-treatment station 15 as vertexes. The closed loop structure may not necessarily be rectangular in shape. For example, it may be contemplated to construct the closed loop structure by laying out the return station 16 along the R color alignment station 13r, the G color alignment station 13g and the B color alignment station 13b which are arranged in a rectilinear pattern.

Next, details of the apparatuses for manufacturing the organic EL devices used in the above-mentioned manufacturing system, i.e., the R color film formation station 14r, the G color film formation station 14g and the B color film formation station 14b will be described referring to FIGS. 1, 2A and 2B.

As shown in FIG. 1, the R color film formation station 14r, the G color film formation station 14g and the B color film formation station 14b (hereinafter these will be referred to simply as “the device manufacturing apparatuses”) each comprise a vacuum chamber 141, a plurality of vapor sources 142a to 142d arranged side by side in the vacuum chamber 141, a conveying means 143 for varying the relative positions of the glass substrate 2 and each of the vapor sources 142a to 142d, and a feeding-in port and a discharging port (both not shown) for feeding the integral-type conveying jig into and out of the vacuum chamber 141.

Of these members, the vapor sources 142a to 142d correspond respectively to a plurality of organic layers 1a to 1d which are to be formed on the glass substrate 2. For example, where the number of the organic layers 1a to 1d is four, as shown in FIG. 2A, it is considered to provide four vapor sources 142a to 142d arranged in a row along the direction in which the relative positions can be varied by the conveying means 143, and to evaporate different organic materials from the vapor sources. It should be noted here that while the case where the number of the vapor sources 142a to 142d arranged in an aligned manner is four is shown as an example, this constitution is naturally not limitative, in the same manner as the case of the number of the organic layers 1a to 1d. Moreover, the number of the organic layer 1a to 1d and the number of the vapor sources 142a to 142d may not necessarily be equal to each other. For example, two or more vapor sources for evaporating the same organic material may be provided side by side; in that case, the number of the vapor sources 142a to 142d is five or more, although the number of the organic layers 1a to 1d is four. Namely, the number corresponding to the organic layers 1a to 1d here includes not only the number equal to the number of the organic layers 1a to 1d but also numbers greater than the number of the organic layers 1a to 1d.

In addition, as shown in FIG. 2B, the vapor sources 142a to 142d are each constituted in a linear form extending in a direction substantially orthogonal to the direction in which the relative positions can be varied by the conveying means 143. Namely, each of the vapor sources 142a to 142d has such a vapor deposition width as to sufficiently cover the length of the side of the glass substrate 2 substantially orthogonal to the moving direction of the glass substrate 2, and a uniform distribution of the organic material will be obtained over the entire range of the vapor deposition width.

Further, each of the vapor sources 142a to 142d is for evaporating the organic material by heating with a heater 144, for example. In this case, an independent temperature controller 145 is connected to each vapor source, and the temperature controller 145 monitors the thickness of the film being formed through a film thickness sensor 146, so that an arbitrary vapor deposition rate is stably maintained. Namely, the vapor deposition rate at each of the vapor sources 142a to 142d is individually controlled by the temperature controller 145 and the film thickness sensor 146. It should be noted here that the system of controlling the vapor deposition rate by the temperature controller 145 and the like is not limitative; namely, it may be considered to provide, for example, a mechanism for individually adjusting the distance between each of the vapor sources 142a to 142d and the glass substrate 2, in place of or in addition to this system.

Incidentally, it is desirable to provide a reserve vapor source installation space in the surroundings of the vapor sources 142a to 142d so that it is possible to easily cope with an increase in the number of the organic layers in the future.

Besides, in FIG. 1, the conveying means 143 is so constructed as to move the integral-type conveying jig inclusive of the glass substrate 2, thereby varying the relative positions between the glass substrate 2 and the vapor sources 142a to 142d. In this case, it may be considered to realize the movement of the conveying jig by adopting a simple system in which a car truck to mount the conveying jig thereon is connected to a closed wire and the wire is pulled at a fixed speed by a servo motor or the like from the exterior, taking into account the need for moving the conveying jig in vacuum, the problem of dust attendant on vapor deposition, and the like. It should be noted here that a conveying system using a ball screw, a belt conveyor or the like which is a known technology may naturally be adopted, provided that a measure for degassing or the like is made.

Next, an example of process in the device manufacturing apparatuses constituted as above, i.e., the method for manufacturing an organic EL device according to the present invention will be described.

In forming the organic EL device 1 on the glass substrate 2, first, a preparatory step in the device manufacturing apparatus, specifically, precise alignment of the glass substrate 2 and the metal mask 3 is conducted at the R color alignment station 13r, the G color alignment station 13g or the B color alignment station 13b. The precise alignment is carried out, for example, by detecting and recognizing a preliminarily applied alignment mark through image processing or the like. After the precise alignment, the glass substrate 2 and the metal mask 3 constitute the integral-type conveying jig through the magnetic force generated by the magnet 4, and the conveying jig is fed into the vacuum chamber 141 of the device manufacturing apparatus through the feeding-in port by the handling robot, conveyor or the like.

In the vacuum chamber 141, where the organic layers 1a to 1d of materials A, B, C and D, for example, are to be formed on the glass substrate 2, the vapor sources 142a to 142d corresponding thereto are arranged in the order of the materials A, B, C and D along the direction in which the relative positions can be varied by the conveying means 143. As has been described above, each of the vapor sources 142a to 142d has such a vapor deposition width as to sufficiently cover the lateral width of the glass substrate 2 and has a uniform distribution.

Therefore, when the integral-type conveying jig fed into the vacuum chamber 141 is moved by the conveying means and a film formation portion of the glass substrate 2 constituting the conveying jig, i.e., the portion of the glass substrate 2 corresponding to an opening 3a formed in the metal mask 3 passes sequentially through positions opposed to the vapor sources 142a to 142d arranged in the order of the materials A, B, C and D, the organic layers 1a to 1d are formed on the film formation portion of the glass substrate 2 in the state of being laminated in the order of the materials A, B, C and D. Namely, the formation of the organic layers 1a to 1d is carried out continuously as the integral-type conveying jig passes over the vapor sources 142a to 142d.

At this time, the vapor deposition rates at the vapor sources 142a to 142d are controlled individually by the temperature controller 145 and the like, according to preset conditions. The vapor deposition rates are so set that the ratios between the film thickness ratios of the organic layers 1a to 1d and the vapor deposition rates of the vapor sources 142a to 142d corresponding thereto are equal and that the vapor deposition rates after the setting are maximized. For this purpose, it suffices to adjust the vapor deposition rates to the one which is most severe as to the heat resistance characteristic of the organic material.

Specifically, it is considered to set the vapor deposition rates at the vapor sources 142a to 142d as follows. For example, there is taken as an example the case where when film formation is conducted at the maximum vapor deposition rates which can be set for the vapor sources 142a to 142d, it takes 10 min, 8 min, 12 min and 5 min respectively for forming the organic layers 1a to 1d in the required film thicknesses. In this case, when the organic layers 1a to 1d are all formed at the maximum vapor deposition rates, the organic layers 1a to 1d will not have the desired film thicknesses, since the integral-type conveying jig passes through the vapor sources 142a to 142d at a fixed velocity. Therefore, in this case, the vapor deposition rates at the vapor sources 142a to 142d are adjusted to the vapor source 142c which corresponds to the longest time of 12 min, and a setting is conducted so that the organic layers 1a to 1d are formed in the desired film thicknesses within that time. At this time, if required, two or more vapor sources corresponding to one organic layer may be provided adjacent to each other, thereby achieving an optimum efficiency of the vapor deposition rates as a whole.

Incidentally, how long times are taken for forming the organic layers 1a to 1d in the required film thicknesses can be determined from the vapor deposition rates at the vapor sources 142a to 142d and the velocity of the integrated-type conveying jig. Therefore, it may be contemplated to control the film thicknesses of the organic layers 1a to 1d by controlling the velocity of the conveying jig.

When the passage of the integral-type conveying jig over the vapor sources 142a to 142d, i.e., the formation of the organic layers 1a to 1d is continuously conducted as above-mentioned, the conveying jig after the film formation is fed out through the discharging port to the exterior of the vacuum chamber 141 of the device manufacturing apparatus by the handling robots, conveyors or the like. Then, the conveying jig is fed to the device manufacturing apparatus corresponding to the next color component, and the same precise alignment and film formation process as the above-described are again performed. This procedure is repeated, whereby the organic EL devices 1 corresponding to the R, G and B color components are arranged in a matrix pattern on the glass substrate 2.

Thus, according to the method for manufacturing the organic EL device 1 and the device manufacturing apparatus for carrying out the method as described in the present embodiment, the integral-type conveying jig inclusive of the glass substrate 2 is moved so as to pass sequentially through the positions opposed to the plurality of vapor sources 142a to 142d arranged side by side, whereby the organic layers 1a to 1d are sequentially laminated at the film formation portion on the glass substrate 2. Namely, the film formation using the vapor deposition material from each of the vapor sources 142a to 142d is conducted at the film formation portion on the glass substrate 2 each time the glass substrate 2 passes sequentially through each of the positions opposed to the vapor sources 142a to 142d.

Therefore, according to the method for manufacturing the organic EL device 1 and the device manufacturing apparatus in the present embodiment, in forming the organic layers 1a to 1d on the glass substrate 2, the preparatory treatments (raising of temperature, stabilization of vapor deposition rate, and the like) for the vapor sources 142a to 142d can be carried out substantially simultaneously. Accordingly, there is no need for surplus time for raising the temperature or stabilizing the evaporation rate on the basis of each organic material, so that speedy formation of the organic layers 1a to 1d can be realized, resulting in that an improvement of the tact time in manufacturing the organic EL device 1 can be expected.

Specifically, in the same manner as in the above-described case, there is taken as an example the case where when the film formation is conducted at the maximum vapor deposition rates which can be set for the vapor sources 142a to 142d, it takes 10 min, 8 min, 12 min and 5 min respectively for forming the organic layers 1a to 1d of the four-layer structure, for example, in the required film thicknesses. In this case, according to the conventional technique, it is considered that it takes 10 min+8 min+12 min+5 min=35 min in total for the film formation. According to the manufacturing method and the device manufacturing apparatus in the present embodiment, on the other hand, the settings are adjusted to the vapor deposition rate corresponding to the longest time, so that 12 min+8 min (the total time for passage through the vapor sources 142a to 142d)=20 min in total for the film formation. As a result, the tact time can be shortened by about 40%.

In addition, according to the method for manufacturing the organic EL device 1 and the device manufacturing apparatus in the present embodiment, the glass substrate 2 passes sequentially through the positions opposed to the vapor sources 142a to 142d, whereby formation of the organic layers 1a to 1d is carried out continuously and, accordingly, the vapor deposition materials from the vapor sources 142a to 142d are wastelessly used for the film formation. Thus, it is possible to contrive enhancement of the efficiency of material consumptions at the vapor sources 142a to 142d, and a reduction in material consumption rate can be expected in the same manner as the reduction in the tact time, so that a reduction in cost of the organic EL device can be expected as compared with the prior art.

Furthermore, according to the method for manufacturing the organic EL device 1 and the device manufacturing apparatus in the present embodiment, formation of the plurality of organic layers 1a to 1d is continuously conducted in one vacuum chamber 141, so that one vacuum chamber 141 suffices even where a multiplicity of organic layers 1a to 1d are to be formed. Namely, it is possible to contrive a speedy film formation process, an enhancement of efficiency of material consumptions and the like without needing a multiplicity of vacuum chambers. Therefore, it is possible to realize an improvement of tact time, a reduction in cost and the like in manufacturing the organic EL device 1, without causing increases in equipment cost, installation space or the like.

Besides, in the device manufacturing apparatus according to the present embodiment, the vapor sources 142a to 142d are each arranged in a linear form extending in a direction substantially orthogonal to the direction in which the relative positions are varied by the conveying means 143. Therefore, the film thickness of each of the organic layer 1a to 1d in the orthogonal direction is made uniform, so that accuracy of the film thickness of each of the organic layers 1a to 1d and the like can be secured very easily even where the organic layers 1a to 1d are formed continuously. While it is desirable that the vapor sources 142a to 142d are each arranged in the above-mentioned linear form, they may not necessarily be arranged in the linear form. For example, even where the vapor sources 142a to 142d are arranged in the form of spots, an arrangement of the spots in an aligned form makes it possible to realize an improvement of manufacturing tact time, a reduction in cost and the like, in the same manner as in the case where the vapor sources 142a to 142d are each arranged in a linear form.

In addition, in the device manufacturing apparatus according to the present embodiment, the conveying means 143 moves the integral-type conveying jig, whereby the relative positions of the glass substrate 2 and each of the vapor sources 142a to 142d are varied. Therefore, the variation of the relative positions can be achieved very easily by a simple method and with high accuracy. It should be noted here that the vapor sources 142a to 142d may naturally be moved, instead of moving the glass substrate 2.

Besides, in the device manufacturing apparatus according to the present embodiment, the temperature controllers 145 and the like are provided correspondingly to the vapor sources 142a to 142d, whereby the vapor deposition rates can be individually controlled on the basis of each of the vapor sources 142a to 142d. Therefore, the film thicknesses of the organic layers 1a to 1d can be set to the desired values, even where the integral-type conveying jig passes over the vapor sources 142a to 142d at a fixed velocity. Further, it is possible to perform feed-back control or the like based on the monitored results of the film thickness on the basis of each of the vapor sources 142a to 142d, so that it is possible to realize a further enhancement of the accuracy of film formation.

According to the system for manufacturing an organic EL display and the manufacturing method using the manufacturing system described in the present embodiment, the conveying jig constituted of the glass substrate 2, the metal mask 3 and the magnet 4 passes sequentially through the R color film formation station 14r, the G color film formation station 14g and the B color film formation station 14b. Therefore, it is possible to continuously construct the organic EL display comprised of the organic EL devices 1 corresponding to the R, G and B color components, and, in this case, it is possible to realize enhancement of the efficiency of the preparatory treatments for film formation, vapor deposition material consumptions and the like, as has been described above for each of the organic EL devices 1.

Furthermore, according to the manufacturing system in the present embodiment, the R color alignment station 13r, the G color alignment station 13g and the B color alignment station 13b individually conduct the alignment corresponding to each color, the patterning film formation corresponding to each color can be performed appropriately, even where the R color film formation station 14r, the G color film formation station 14g and the B color film formation station 14b continuously form the organic EL devices 1 for each color.

In addition, according to the manufacturing system in the present embodiment, the closed loop structure is constructed due to the presence of the return station 16, so that the conveying jig is circulated in the closed loop. Therefore, even where the organic EL devices 1 corresponding to the color components are formed continuously, it is possible to realize full automation of the series of processing, which is very suitable for contriving enhancement of the efficiency in manufacturing the organic EL display.

Particularly, as has been described above, where the closed loop structure is rectangular in shape, the moving distance of the conveying jig by the return station 16 can be most shortened, and the installation area of the manufacturing system can be reduced, resulting in that it is possible to easily realize reductions in the size and cost of the system, and the like.

While specific examples of carrying out the present invention have been described in the present embodiment, the invention is not limited to the examples, and various modifications are possible. Namely, the materials, the shapes, the operating mechanisms and the like of the series of component elements constituting the device manufacturing apparatus described in the present embodiment are not limitative, and they can be freely modified as far as the functions of each of the component elements can be secured in the same manner as above. In this case, also, the same effects as in the present embodiment can be obtained. For example, while the case where the organic EL devices 1 are formed on a plate-like glass substrate 1 has been described as an example in the present embodiment, it is possible to cope in the same manner with a roll-like substrate such as a film material consisting of a resin material.

What is claimed is:

1. A method for manufacturing an organic electroluminescence device comprising a plurality of layers sequentially laminated on a substrate, wherein
said plurality of layers are laminated at a film formation portion on said substrate by varying the relative positions of said substrate and a plurality of vapor sources arranged side by side so that said substrate passes sequentially through positions opposed to said plurality of vapor sources.

2. An apparatus for manufacturing an organic electroluminescence device comprising a plurality of layers sequentially laminated on a substrate, wherein
a plurality of vapor sources corresponding to said plurality of layers are arranged in an aligned manner, and
a conveying means is provided for varying the relative positions of said substrate and said plurality of vapor sources so that a film formation portion on said substrate passes sequentially through positions opposed to said plurality of vapor sources.

3. An apparatus for manufacturing an organic electroluminescence device as set forth in claim 2, wherein
all of said plurality of vapor sources are provided in a linear form extending in a direction substantially orthogonal to the direction in which the relative positions are varied by said conveying means.

4. An apparatus for manufacturing an organic electroluminescence device as set forth in claim 2, wherein
said conveying means moves said substrate so as thereby to vary the relative positions of said substrate and said plurality of vapor sources.

5. An apparatus for manufacturing an organic electroluminescence device as set forth in claim 2, wherein
a control means is provided for controlling the vapor deposition rate individually on the basis of each of said plurality of vapor sources.

6. A system for manufacturing a display unit using organic electroluminescence devices each of which comprises a plurality of layers sequentially laminated on a substrate, wherein
said manufacturing system comprises a plurality of apparatuses for manufacturing an organic electroluminescence device in which a plurality of vapor sources corresponding to said plurality of layers are arranged in an aligned manner, and a conveying means is provided for varying the relative positions of said substrate and said plurality of vapor sources so that a film formation portion on said substrate passes sequentially through positions opposed to said plurality of vapor sources; and
said manufacturing apparatuses respectively form said organic electroluminescence devices corresponding to different color components.

7. A system for manufacturing a display unit using organic electroluminescence devices as set forth in claim 6, wherein
said substrate and a mask used for patterning said film formation portion on said substrate pass sequentially through said manufacturing apparatuses.

8. A system for manufacturing a display unit using organic electroluminescence devices as set forth in claim 7, wherein
an alignment device for position matching between said substrate and said mask is provided at the preceding stage of each of said manufacturing apparatuses.

9. A system for manufacturing a display unit using organic electroluminescence devices as set forth in claim 8, wherein
a return device for supplying said mask having passed through said manufacturing apparatus at the last stage to said alignment device at the beginning stage is provided in addition to said plurality of manufacturing apparatuses and said alignment devices arranged correspondingly to said manufacturing apparatuses, and said manufacturing apparatuses, said alignment devices and said return device constitute a closed loop structure.

10. A system for manufacturing a display unit using organic electroluminescence devices as set forth in claim 9, wherein
said closed loop structure comprises said manufacturing apparatuses and said return device arranged in a rectangular pattern with said alignment devices as vertexes.

11. A method for manufacturing a display unit using organic electroluminescence devices each of which comprises a plurality of layers sequentially laminated on a substrate, wherein
an organic electroluminescence device corresponding to one color component is produced by laminating a plurality of layers at a film formation portion on said substrate through varying the relative positions of said substrate and a plurality of vapor sources arranged side by side so that said substrate passes sequentially through positions opposed to said plurality of vapor sources, and
this procedure is repeated more than once while changing said film formation portion on said substrate so as thereby to arrange said organic electroluminescence devices corresponding to a plurality of color components on said substrate.
